(19) United States
(12) Patent Application Publication
(10) Pub. No.: US 2003/0111008 A1
(43) Pub. Date: Jun. 19, 2003

(54) Method for the epitaxy of (indium, aluminum, gallium) nitride on foreign substrates

(76) Inventors: Andre Strittmatter, Berlin (DE); Alois Krost, Berlin (DE); Dieter Bimberg, Berlin (DE)

Correspondence Address: BRUCE LONDA, NORRIS, MCLAUGHLIN & MARCUS, P.A., 220 EAST 42ND STREET, 30TH FLOOR, NEW YORK, NY, 10017, US

(21) Appl. No.: 10/111,275

(22) PCT Filed: Aug. 22, 2001
(86) PCT No.: PCT/EP01/09713

(30) Foreign Application Priority Data
Aug. 22, 2000 (DE) 100 41 285.8

(51) Int. Cl. C30B 23/00; C30B 25/00; C30B 28/12; C30B 28/14

(52) U.S. Cl. 117/95

(57) ABSTRACT

The invention relates to a process for the epitaxy of (indium, aluminum, gallium) nitride on foreign substrates.

The object of the invention is to find a maskless process which nevertheless achieves the advantages of reduced dislocation by using lateral overgrowth.

Said object is accomplished in that indentations (7) are provided on the surface of substrates (1), the walls (4) of said indentations (7) being such that the growth fronts of the (In,Al,Ga)N layers (3) on the bottoms of the indentations (7) are separated from those on the protrusions (6) situated therebetween.

The invention relates to a process for the epitaxy of (indium, aluminum, gallium) nitride on foreign substrates according to the preamble of claim 1.

(In,Al,Ga)N layers are widely used in opto-electronic and electronic semiconductor components.

Almost exclusively, foreign substrates such as sapphire, silicon carbide or silicon have been used in the epitaxy of (In,Al,Ga)N to date. They exhibit substantial mismatch in their lattice constants (3-40%), and as a consequence, a high density of dislocations (10⁸−10¹⁰ cm⁻²) invariably must be formed in a growing layer, deteriorating the performance of such components (S. Nakamura et al., Appl. Phys. Lett. 72, 1998, p. 211). In recent years, so-called lateral over-growth is used to decrease the dislocation density (Y. Kato et al., J. Cryst. Growth 144, 1994, p. 133; T. S. Zheleva et al., Appl. Phys. Lett. 71, 1997, p. 2472; K. Linthicum et al., Appl. Phys. Lett. 75, 1999, p. 196; J. A. Smart et al., Appl. Phys. Lett. 75, 1999, p. 3820). Therein, use is made of the fact that a laterally growing layer can grow within its natural crystallinity with no epitaxial relationship to the substrate and without forming dislocations. Lateral overgrowth is achieved by coating a mask (e.g. one made of SiO₂ or SiNₓ) on the surface, on which mask no growth of (In,Al,Ga)N takes place when suitably selecting the parameters. The mask is provided with parallel openings in the form of stripes wherein growth of (In,Al,Ga)N can take place. When the growth front reaches the upper edge of the mask, the material can grow in lateral direction over the mask, with no dislocation taking place. After an appropriate period of growth, the layer can close above the mask. This process involves problems related to coating the mask. When coating the mask on a grown (In,Al,Ga)N layer, the epitaxy process has to be interrupted and restarted after coating the mask. When coating the mask prior to epitaxy, the substrate is lacking a homogeneous surface, so that the begin of epitaxy on the substrate, which is the crucial point for the ensuing optical and crystallographic quality of the layer, has to be re-optimized, thus restricting the potential choice of parameters (J. A. Smart et al., Appl. Phys. Lett. 75, 1999, p. 3820). Furthermore, the additional introduction of thermally induced strain on the surface is undesirable in the use of masks. As a rule, the mask has a thermal expansion which is different from that of the (In,Al,Ga)N layer, thereby straining the layer upon heating and/or cooling (T. S. Zheleva et al., Appl. Phys. Lett. 74, 1999, p. 24931). In addition, the use of masks disadvantageously involves potential incorporation of impurities in the layer as a result of mask erosion (Q. K. K. Liu et al., T. S. Zheleva et al., Appl. Phys. Lett. 74, 1999, p. 3122).

The object of the invention is therefore to find a maskless process which nevertheless achieves the advantages of reduced dislocation by using lateral overgrowth.

Said object is accomplished with the characterizing section of claim 1.

Advantageous embodiments of the invention will be set forth in the subclaims.

The process of the invention involves one form of the so-called lateral overgrowth of (In,Al,Ga)N on foreign substrates, wherein pre-structuring of the substrate is effected by way of indentations and protrusions, the specific properties of the lateral walls of the indentations resulting in an initial separation of growth of the (In,Al,Ga)N layer in growth fronts on the bottoms of the indentations and on the protrusions situated therebetween.

Structuring the substrates in indentations and protrusions enables lateral overgrowth from the protrusions beyond the openings of the indentations. One precondition is separating the growth on the bottoms of the indentations from that on the protrusions, which can be achieved by preparing the side walls of the pits. If, as a result of such preparation, e.g. by passivation using an inert material, no or only little growth occurs on the walls, separate growth fronts will inevitably be formed.

In this process, a maskless, uniform surface (passivated side walls in the indentations are not essential for the material growing from the protrusions) is provided at the beginning of epitaxy, thus causing neither additional thermal strain, nor additional impurities in the layer, nor a substantial change in growth parameters at the beginning of growth.

Group III nitrides are mainly deposited on foreign substrates such as sapphire, SiC or Si in order to obtain semiconductor components such as LEDs and lasers. High lattice mismatch between the layer and each of these substrates results in a high dislocation density in these layers, impairing the optical and electrical properties of components. Advantageously, a reduction in dislocation density can be achieved by using the method of lateral overgrowth wherein portions of a continuous layer are joined. The laterally growing portions of the layer have a significantly reduced dislocation density.

The methods of lateral overgrowth used to date require a mask made of e.g. SiNₓ. As a rule, coating such a mask requires growth interruption or modified process control during nucleation of the nitride layers on the substrate. In contrast, use of a mask is not required in the process according to the invention, and as a result, the process neither has to be interrupted nor modified during nucleation of the nitride layers.

The process according to the invention is based on substrate structuring in the form of indentations and protrusions with suitable preparation of the walls of said indentations, so that from the beginning, growth is divided in growth fronts on the protrusions and growth fronts in the indentations. During growth, the laterally growing portions of the layer close above the indentations to form a closed layer.

The development according to subclaim 2 describes a useful way of structuring the indentations in the form of parallel pits. The regularity of such structuring results in an improved control of overgrowth, because said overgrowth proceeds across the pits.

The inventive embodiment of subclaim 3 involves a useful crystallographic orientation of the pits relative to the substrate surface, resulting in the formation of well-defined lateral facets of the growing crystal, which provides improved control of layer intergrowth, because each crystal facet grows at a specific growth rate.

Subclaim 4 represents another advantageous embodiment in such a way that separation of the growth fronts is achieved by sufficient steepness of the indentation walls, so that additional process steps for lateral wall preparation are not required.

Subclaim 5 takes into account that the growth fronts will remain separated even after completed overgrowth (the layer extending from the protrusions has closed above the bottom of an indentation), thus avoiding propagation of dislocations from the bottom of the indentation into the overgrowing layer.

Subclaim 6 achieves the object using specifically Si substrates, the use of which as substrate material enabling a particularly cost-effective design, because these materials are particularly low in cost per unit area and permit combination with existing processes in microelectronics.

The invention will be illustrated in more detail with reference to the drawings and one example.

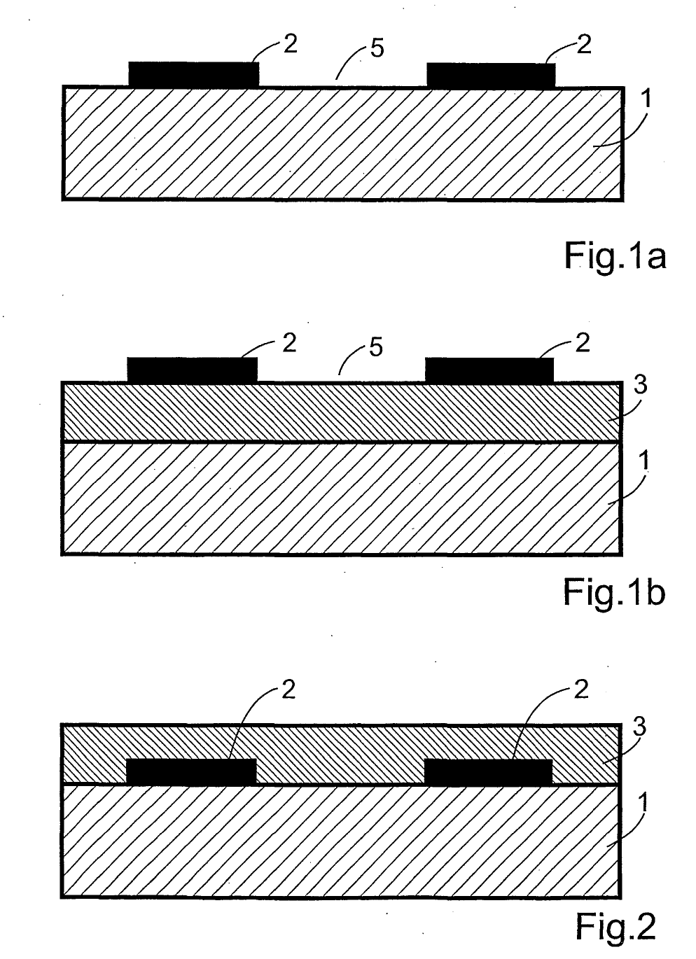

FIG. 1a shows a schematic diagram of a stripe mask directly coated on the substrate;

FIG. 1b shows a schematic diagram of a stripe mask coated on a previously grown (In,Al,Ga)N layer;

FIG. 2 shows a schematic diagram of an overgrowing layer having closed above the mask; and

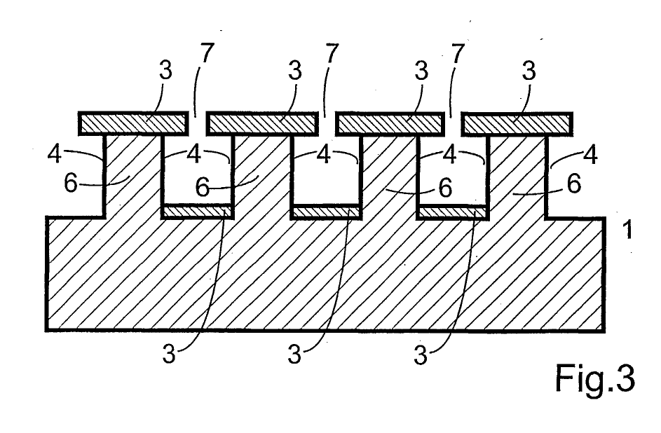

FIG. 3 shows a schematic diagram of growth on a structured substrate.

So-called lateral overgrowth is well-known, which is utilized to reduce the dislocation density. To this end, use is made of the fact that a laterally growing layer can grow within its natural crystallinity with no epitaxial relationship to the substrate and without forming dislocations. As schematically illustrated in FIG. 1a and FIG. 1b, lateral overgrowth is achieved by coating a mask 2 on a substrate 1, on which mask no growth of (In,Al,Ga)N takes place when suitably selecting the parameters. The mask 2 is provided with parallel openings 5 in the form of stripes wherein growth of (In,Al,Ga)N can take place. When the growth front of the (In,Al₁,Ga)N layer 3 reaches the upper edge of mask 1, the material can grow in lateral direction over the mask 2, with no dislocation taking place. After an appropriate period of growth, the (In,Al,Ga)N layer 3 can close above the mask, as illustrated in FIG. 2. This process involves problems related to coating the mask 2. When coating the mask 2 on a grown (In,Al,Ga)N layer 3, as illustrated in FIG. 1b, the epitaxy process has to be interrupted and restarted after coating the mask 2. When coating the mask 2 prior to epitaxy, as illustrated in FIG. 1a, the substrate is lacking a homogeneous surface, so that the begin of epitaxy on the substrate 1, which is the crucial point for the ensuing optical and crystallographic quality of the (In,Al,Ga)N layer 3, has to be re-optimized, thus restricting the potential choice of parameters.

FIG. 3 shows a schematic representation of the proposal according to the invention. Structuring the substrates 1 in the form of indentations 7 and protrusions 6 enables lateral overgrowth from the protrusions 6 beyond the indentations 7. One precondition is separating the growth on the bottoms of the indentations 7 from that on the protrusions 6, which can be achieved by preparing the side walls 4 of the indentations 7. If, as a result of such preparation, e.g. by passivation using an inert material, no or only little growth occurs on the walls 4, separate growth fronts will inevitably be formed.

### EXAMPLE

### Related to Si Substrates

Initially, a silicon substrate with Si(lll) surface is coated with a photosensitive resist mask, and a stripe structure with e.g. 5 μm spacing is applied using conventional photolithography. Into the surface thus provided with a mask, the pit structure is etched at a depth of e.g. 4 μm, using an etching process (e.g. ion etching), and the resist mask is subsequently removed using so-called removers. Now, the substrate consists uniformly of an Si surface with non-treated ridges and etched pit bottoms, the lateral walls of which may have an undercut as a result of the anisotropy of typical etching processes on Si(111) surfaces. Subsequently, the structured substrate can be prepared for epitaxy in the same way as a planar standard substrate, and epitaxy can be performed as described in e.g. Phys. Stat. Sol. (b) 216 (1999), p. 611 (A. Strittmatter et al.). To enhance lateral growth, the parameters can be modified as in MRS Internet J. Nitride Semicond. Res 4S1, G4.5 (1999); H. Marchand et al.).

In analogy, this example can be applied to any other substrate suitable for epitaxy of (in,ga,al) nitride layers, particularly to sic and sapphire substrates.

### Key to the Drawings

1 substrate

2 mask

3 (in,ga,al)n layer

4 wall

5 opening

6 protrusions

7 indentations

1. A process for the epitaxy of (indium, aluminum, gallium) nitride on foreign substrates, characterized in that
indentations (7) are provided on the surface of substrates (1), the walls (4) of said indentations (7) being such that the growth fronts of the (In,Al,Ga)N layers (3) on the bottoms of the indentations (7) are separated from those on the protrusions (6) situated therebetween.

2. The process according to claim 1, characterized in that
the indentations (7) are designed in the form of parallel pits.

3. The process according to claims 1 to 2, characterized in that
the indentations (7) are designed in the form of parallel pits and oriented along a crystallographic direction on the surface of the substrate (1).

4. The process according to claims 1 to 3, characterized in that
the lateral walls (4) of the indentations (7) are of sufficiently steep design, so that the growing layer at the bottoms of the indentations (7) is separated from the growing layer on the protrusions (6) between the indentations (7).

5. The process according to claims 1 to 4, characterized in that
the ratio of the depth of the indentation (7) and the width thereof is selected such that, given lateral and vertical growth rates of the (In,Al,Ga)N layer (3), the indentations (7) are laterally overgrown, starting from the protrusions (6), with no contact existing between the layer growing on a bottom and the overgrowing layer, until the overgrowing layer has closed above the indentation.

6. The process according to claims 1 to 5, characterized in that
an Si substrate is used.
